(19) United States
(12) Patent Application Publication
(10) Pub. No.: US 2023/0395633 A1
(43) Pub. Date: Dec. 7, 2023

(54) IMAGE SENSOR PACKAGING STRUCTURES AND RELATED METHODS

(71) Applicant: SEMICONDUCTOR COMPONENTS INDUSTRIES, LLC, Phoenix, AZ (US)

(72) Inventor: Shou-Chian HSU, Zhubei City (TW)

(73) Assignee: SEMICONDUCTOR COMPONENTS INDUSTRIES, LLC, Phoenix, AZ (US)

(21) Appl. No.: 17/664,138

(22) Filed: May 19, 2022

(51) Int. Cl. H01L 27/146

(52) U.S. Cl. CPC H01L 27/14636; H01L 27/14683; H01L 27/14618

(57) ABSTRACT

An image sensor package may include an image sensor die including a bond pad and an optically transmissive lid coupled over the bond pad at an adhesive dam, the adhesive dam including a first layer directly coupled to a largest planar surface of the optically transmissive lid and a second optically opaque layer coupled over the bond pad.

### BACKGROUND

### 1. Technical Field

Aspects of this document relate generally to semiconductor device packages, such as packages for image sensors.

### 2. Background

Semiconductor device packages have been devised that work to protect semiconductor die and allow them to be electrically connected to a circuit board or motherboard. As semiconductor die are vulnerable to damage when exposed to moisture or physical movement (via dropping, vibration, etc.), semiconductor device packages mechanically support the semiconductor die and prevent contaminants from reaching the material of the semiconductor die.

### SUMMARY

An image sensor package may include an image sensor die including a bond pad and an optically transmissive lid coupled over the bond pad at an adhesive dam, the adhesive dam including a first layer directly coupled to a largest planar surface of the optically transmissive lid and a second optically opaque layer coupled over the bond pad.

Implementations of image sensor packages may include one, all, or any of the following:

The optically opaque layer may be a bonding glue.

The second optically opaque layer completely covers an entire area of the bond pad.

The adhesive dam may be coupled in a non-active area of the image sensor die.

The package may include a through-silicon-via coupled with the bond pad.

The package may include a substrate coupled to a side of the image sensor die not coupled to the optically transmissive lid.

The package may include a redistribution layer coupled to a side of the image sensor die not coupled to the optically transmissive lid.

Implementations of an image sensor package may include a plurality of bond pads of an image sensor die and an adhesive dam, the adhesive dam including a first layer and a second optically opaque layer directly coupled to the plurality of bond pads.

Implementations of image sensor packages may include one, all, or any of the following:

The second optically opaque layer may be a bonding glue.

The second optically opaque layer completely covers all of the plurality of bond pads.

The adhesive dam may be coupled in a non-active area of the image sensor die.

The package may include an optically transmissive lid coupled to the first layer of the adhesive dam.

The package may include a substrate coupled to a side of the image sensor die not coupled to the optically transmissive lid.

The package may include a redistribution layer coupled to a side of the image sensor die not coupled to the optically transmissive lid.

Implementations of a method of forming an image sensor package may include providing an optically transmissive substrate; patterning a first layer of an adhesive dam on a largest planar surface of the optically transmissive substrate; applying an optically opaque layer directly onto the first layer; bonding the optically transmissive substrate to a semiconductor substrate including a plurality of image sensor die using the optically opaque layer; forming a plurality of electrical interconnects to the plurality of image sensor die; and singulating the optically transmissive substrate and semiconductor substrate to form a plurality of image sensor packages.

Implementations of a method of forming an image sensor package may include one, all, or any of the following:

Forming a plurality of electrical interconnects further may include forming a plurality of through-silicon-vias in the semiconductor substrate to a plurality of bond pads of the plurality of image sensor packages.

The plurality of image sensor die may each include a plurality of bond pads and the optically opaque layer completely covers all of the plurality of bond pads.

Forming a plurality of electrical interconnects further may include forming a redistribution layer on a side of the semiconductor substrate opposite that to which the optically transmissive substrate may be bonded.

Forming a plurality of electrical interconnects further may include coupling a substrate array to a side of the semiconductor substrate opposite that to which the optically transmissive substrate may be bonded.

The method may include thinning the semiconductor substrate after bonding to the optically transmissive substrate.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross sectional view of an implementation of a image sensor package;

FIG. 2 is a cross sectional view of another implementation of an image sensor package with magnification area;

FIG. 3 is a magnified cross sectional view of the magnification area shown in FIG. 2;

FIG. 4 is a side view of an optically transmissive substrate;

FIG. 5 is a side view of the optically transmissive substrate of FIG. 4 following application of a first layer of an adhesive dam to form a pattern on the surface of the substrate;

FIG. 6 is a side view of the optically transmissive substrate of FIG. 5 following application of an optically opaque layer onto the first layer;

FIG. 7 is a side view of the optically transmissive substrate of FIG. 6 following bonding with a semiconductor substrate comprising a plurality of image sensor die;

FIG. 8 is a side view of the bonded optically transmissive substrate and semiconductor substrate following formation of electrical interconnects; and

FIG. 9 is a side view of an image sensor package following singulation of the bonded optically transmissive substrate and semiconductor substrate.

### DESCRIPTION

This disclosure, its aspects and implementations, are not limited to the specific components, assembly procedures or method elements disclosed herein. Many additional components, assembly procedures and/or method elements known in the art consistent with the intended image sensor packages will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such image sensor packages, and implementing components and methods, consistent with the intended operation and methods.

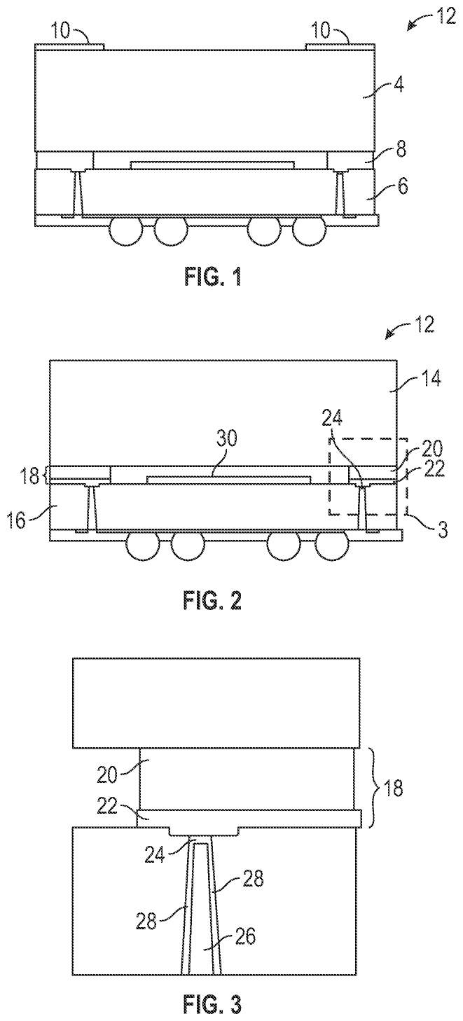

Referring to FIG. 1, an implementation of an image sensor package 2 is illustrated. In this package implementation, an optically transmissive lid 4 is bonded to an image sensor die 6 through an adhesive dam 8 that is a single layer of bonding glue made of a material capable of allowing light to transmit through it. A layer of light shield material 10 is placed on the largest planar surface of the optically transmissive lid 4 that is opposite the largest planar surface bonded to the image sensor die 6.

In various image sensor package designs, observations have shown that the metal bond pads adjacent the active area of the image sensor and the bonding glue itself create light reflection and light scattering when incident light contacts them. This light reflection and scattering can appear in images collected by the image sensor as flare. The light shield layer 10 in the package 2 of FIG. 1 can offer some improvement as it can prevent direct incident light from contacting the bond pads, but light coming in at angles less than normal to the light shield layer can still reach the pads and the bonding glue. Furthermore, the location of the light shield layer will obstruct the visual inspection path needed to do visual inspection for packaging defects like bubbles in the adhesive dam or delamination of the adhesive dam which can cause reliability problems for the image sensor during long-term operation of the sensor.

Referring to FIG. 2, another implementation of an image sensor package 12 is illustrated. Like the package of FIG. 1, the package 12 includes an optically transmissive lid 14 and an image sensor die 16 bonded with an adhesive dam 18 that has two layers. The first layer 20 of the adhesive dam 18 is made of a bonding glue or other adhesive that can be similar to the material of the adhesive dam 8 in FIG. 1 which can allow at least some electromagnetic radiation to pass through it. The second layer of the adhesive dam 18 is made of an optically opaque material (optically opaque layer 22) and is directly coupled to/over bond pad 24. Because in various implementations the optically opaque layer 22 completely covers the bond pad 24 directly above the bond pad 24 (and any other pads of a plurality of bond pads that may be included in a given image sensor die design), the ability for electromagnetic radiation from any angle to contact the bond pad 24 may be essentially eliminated. This ability of the optically opaque layer 22 to prevent electromagnetic radiation from reaching the bond pad 24 allows for a significant reduction in observed flare by eliminating or substantially reducing reflection rom the bond pad 24. Also, the optically opaque layer 22 can reduce reflection from the material of the first layer 20 as any electromagnetic radiation directed into the material of the layer 22 by reflections from the first layer 20 can be absorbed. Also, since no reflection takes place from the optically opaque layer itself, electromagnetic radiation passing through the first layer 20 does not return back through the first layer 20 as reflected electromagnetic radiation and contribute to reflection from the first layer.

FIG. 3 illustrates a magnified view of the region 3 indicated in FIG. 2 of the image sensor package 12 and shows the location of the first layer 20, optically opaque layer 22, adhesive dam 18, and bond pad 24. In particular implementations, the optically opaque layer 22 may be an epoxy adhesive that contains a pigment(s) that help ensure the adhesive is opaque to a desired wavelength or range of wavelengths of electromagnetic radiation. A particular implementation may utilize an epoxy adhesive manufactured by Masterbond of Hackensack, New Jersey. In a particular implementation, the pigment may be carbon black.

Note that in this particular image sensor package design, a through-silicon-via 26 has been used with traces 28 formed thereon to form an electrical connection with the bond pad 24 and the rest of the package design. While the use of through-silicon-vias is illustrated in the various package designs in this document, other electrical connection techniques may be used. As a non-limiting example, a trace could be formed from the bond pad across the sidewall of the image sensor die to allow for connection of the bond pad. In other implementations, the bond pad may be connected internally to other electrical routing provided by a second die bonded to the image sensor die. By non-limiting example, in various implementations, the image sensor die may be bonded to one or more additional die, such as signal processing die, memory die, processors, or any other semiconductor die type. The die-to-die bonding may be fusion bonding or hybrid bonding in various implementations. The image sensor die itself may be a front-side integrated (FSI) sensor or, as in the die illustrated in FIGS. 2 and 3, a back-side integrated (BSI) sensor. While the area of the pixel array 30 is illustrated in FIG. 2 has being on the surface of the image sensor die 16, this is merely for purposes of convenient illustration as in a BSI sensor, the actual pixels used to sense electromagnetic radiation are located beneath the surface of the semiconductor material used for the image sensor. In other image sensor package implementations, however, the multiple die may not be fusion or hybrid bonded, but may be bonded using a die attach film, an adhesive, electrical connections, or other die-to-die bonding techniques. As used herein, the term “non-active area” of the image sensor die includes the area just outside of the area formed by pixel array 30 out to the outer edge of the bond pad(s) 24.

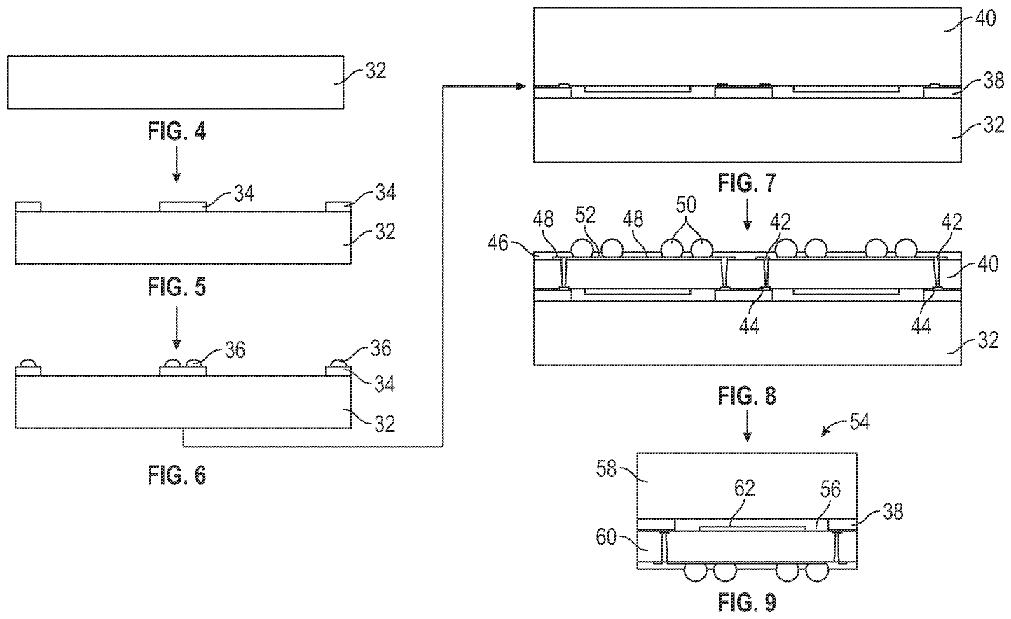

Referring to FIG. 4, an implementation of an optically transmissive substrate 32 is illustrated following completion of a cleaning process for the largest planar surfaces of the substrate. In a particular implementation, the optically transmissive substrate 32 is made of glass. In various implementations, one or more layers of anti-reflective coating materials may be applied to one or both of the largest planar surfaces of the optically transmissive substrate 32. FIG. 5 illustrates a side cross-sectional view of the optically transmissive substrate 32 after application of a first layer 34 of material of an adhesive dam. Note that FIG. 5 illustrates that the first layer 34 forms a pattern of material on one of the largest planar surfaces of the optically transmissive substrate 32. The process of forming the pattern of material that forms the first layer 34 may be carried out using a wide variety of patterning methods and systems, such as, by non-limiting example, stencil printing, lithography, screen printing, dispensing, spraying, stamping, or any other method for pattering a layer of material. FIG. 6 illustrates, the optically transmissive substrate 32 following application of the material of the optically opaque layer 36. Where the material of the optically opaque layer 36 is a bonding glue, it may be applied over the first layer 34 using various methods, including, by non-limiting example, dispensing, spraying, stenciling, or any other method of patterning a layer of material. In some method implementations, the material of the first layer 34 may be partially cured or cured to a B Stage to ensure it remains in place while the material of the optically opaque layer 36 is applied to it. Also, in some method implementations, the optically opaque layer 36 may be partially cured or cured to a B stage to allow for handling of the optically transmissive substrate 32. However, other implementations, no curing of the optically opaque layer and/or the first layer may be used during processing.

Following formation of the two layers of the adhesive dam 38, FIG. 7 illustrates the optically transmissive substrate 32 after bonding to a semiconductor substrate 40 that includes a plurality of image sensor die therein/thereon. The bonding process used to bond the material of the adhesive dam 38 may be one specific to the material type(s) used for the layers of material for the adhesive dam, such as, by non-limiting example, thermal compression bonding, thermal curing, ultraviolet light curing, temperature ramping, any combination thereof, or any other technique for causing the material of the adhesive dam 38 to set and/or adhere to the material of the semiconductor substrate. During the bonding process, an alignment process is used that ensures that the pattern of the adhesive dam 38 aligns with the locations of the bond pads of each of the image sensor die included in the semiconductor substrate 40. A wide variety of alignment methods and/or systems could be used in various implementations, including, by non-limiting example, notch aligning both substrates, using an aligner tool to align the optically transmissive substrate to alignment features on the semiconductor substrate, visual alignment through the optically transmissive substrate, a jig, or any other method of ensuring adequate registration between the pattern of the adhesive dam and the pattern of bond pads on the semiconductor substrate.

Following bonding of the optically transmissive substrate 32 to the semiconductor substrate 40 via the adhesive dam 38, additional processing steps are carried out on the semiconductor substrate to form a plurality of interconnects to the image sensor die included in the semiconductor substrate 40. In some implementations, a substrate thinning process is carried out to reduce the thickness of the substrate to a desired value. Various thinning processes may be used, including, by non-limiting example, backgrinding, lapping, polishing, etching, chemical mechanical planarization, and any other method of removing material from a semiconductor substrate. As illustrated in FIG. 8, through-silicon-vias 42 have been formed through the material of the semiconductor substrate (silicon in this case) to allow for routing of electrical connections from the bond pads 44 to the side of the semiconductor substrate 40 opposite the side to which the optically transmissive substrate 32 is bonded. While the use of through-silicon-vias is illustrated in FIG. 8, the vias could be through-oxide or through whatever material type the substrate is made of (gallium arsenide, silicon-on-insulator, sapphire, ruby, etc.).

FIG. 8 illustrates that additional structures may be formed to further establish electrical connections. FIG. 8 illustrates an implementation of a redistribution layer 46 formed on the semiconductor substrate that includes traces 48 and additional bond pads formed that are connected to solder balls 50 that are added and coupled using a ball drop process. While the use of a ball drop process is illustrated in FIG. 8, the use of corresponding processes to form/apply copper pillars, copper bumps, studs, or stud bumps may be utilized in various method implementations where such interconnect types are used. Associated passivation materials 52 are also formed over the traces 48 and around the bond pads for the solder balls 50. These passivation materials may include one or more layers of various materials including, by non-limiting example, polyimide, silicon nitride, silicon oxide, benzocyclobutene, or any other material resistant to moisture and/or cracking. In this way, an electrical connection from the pads 44 is routed out to the solder balls 50 allowing the image sensor die in the semiconductor substrate 40 to electrically and mechanically couple with a circuit board or motherboard to which they will ultimately be placed.

FIG. 9 illustrates an image sensor package 54 formed by singulating the semiconductor substrate 40 and the optically transmissive substrate 32 using any of a wide variety of singulation methods. These may include, by non-limiting example, sawing, lasering, etching, scribing, any combination thereof, or any other method of separating two materials. At this point, the material of the adhesive dam 38 works to seal an air gap 56 formed between the optically transmissive lid 58 and the image sensor die 60. While the use of an air gap 56 in the image sensor package 54 illustrated in FIG. 9 is illustrated, in other implementations, no air gap may be present as an additional material with a predefined index of refraction may be formed over the pixel array 62 that is sized to fill or substantially fill the area between the adhesive dam 38. In other implementations, the material with the predefined index of refraction may be placed into the spaces between the adhesive dam 38 and hardened/cured prior to the bonding of the optically transmissive substrate 32 to the semiconductor substrate 40. In this way a gapless or substantially gapless image sensor could be formed which also has the ability to reduce flare using the optically opaque layer.

While the process disclosed in FIGS. 4-9 involves formation of an image sensor package with a redistribution layer, in other package implementations, a redistribution layer may not be formed and a substrate coupled to the image sensor die instead. In such implementations, a mold compound may be applied around the image sensor die and placed in contact with at least a portion of the adhesive dam and, in some implementations, placed in contact with the sidewalls of the optically transmissive lid. Where a substrate is used, a wide variety of interconnect types could be employed to connect the substrate to a circuit board or motherboard including, by non-limiting example, pads, pins, balls, copper pillars, studs, stud bumps, solder bumps, or any other interconnect type. The mold compound may include any of a wide variety of components, including, by non-limiting example, epoxies, resins, pigments, strengthening materials, or any other mold compound component. Also, in various method implementations where a substrate is being used, an array of substrates may be coupled to the semiconductor substrate prior to the singulation step. In such implementations, the resulting substrate is the same size as the optically transmissive lid and the image sensor die and so an additional mold compound may not be used.

In some implementations, the use of a leadframe rather than a substrate may also be employed. In such implementations, a leadframe panel may be coupled to the semiconductor substrate. During various method implementations, the leadframe may be singulated at the same time as the optically transmissive substrate and semiconductor substrate, or the leadframe may be separately singulated following singulation of the two substrates. Any of the mold compound implementations disclosed herein may be employed to help form a final protective seal around the leadframe components as needed in various package implementations.

In some implementations, the image sensor die may be directly bonded to the circuit board or motherboard without the formation of a redistribution layer or use of a substrate or leadframe. In such implementations, because the optically transmissive lid has already been bonded to the image sensor die, the resulting device will still have the same anti-flare capabilities because of the use of the optically opaque layer in the adhesive dam.

Where multiple die are bonded or coupled together to form the ultimate image sensor die as previously discussed, the various method implementations disclosed herein would be correspondingly modified to include the additional interconnect forming, bonding, thinning, and other semiconductor processing steps needed to accommodate the stacking and interconnecting of the multiple die. Those of ordinary skill will readily be able to create various method implementations using the principles disclosed in this document to accommodate multi-die image sensor packages that include an optically opaque layer.

In places where the description above refers to particular implementations of image sensor packages and implementing components, sub-components, methods and sub-methods, it should be readily apparent that a number of modifications may be made without departing from the spirit thereof and that these implementations, implementing components, sub-components, methods and sub-methods may be applied to other image sensor packages.

What is claimed is:

1. An image sensor package comprising:
an image sensor die comprising a bond pad; and
an optically transmissive lid coupled over the bond pad at an adhesive dam, the adhesive dam comprising a first layer directly coupled to a largest planar surface of the optically transmissive lid and a second optically opaque layer coupled over the bond pad.

2. The package of claim 1, wherein the optically opaque layer is a bonding glue.

3. The package of claim 1, wherein the second optically opaque layer completely covers an entire area of the bond pad.

4. The package of claim 1, wherein the adhesive dam is coupled in a non-active area of the image sensor die.

5. The package of claim 1, further comprising a through-silicon-via coupled with the bond pad.

6. The package of claim 1, further comprising a substrate coupled to a side of the image sensor die not coupled to the optically transmissive lid.

7. The package of claim 1, further comprising a redistribution layer coupled to a side of the image sensor die not coupled to the optically transmissive lid.

8. An image sensor package comprising:
a plurality of bond pads of an image sensor die; and
an adhesive dam, the adhesive dam comprising a first layer and a second optically opaque layer directly coupled to the plurality of bond pads.

9. The package of claim 8, wherein the second optically opaque layer is a bonding glue.

10. The package of claim 8, wherein the second optically opaque layer completely covers all of the plurality of bond pads.

11. The package of claim 8, wherein the adhesive dam is coupled in a non-active area of the image sensor die.

12. The package of claim 8, further comprising an optically transmissive lid coupled to the first layer of the adhesive dam.

13. The package of claim 12, further comprising a substrate coupled to a side of the image sensor die not coupled to the optically transmissive lid.

14. The package of claim 12, further comprising a redistribution layer coupled to a side of the image sensor die not coupled to the optically transmissive lid.

15. A method of forming an image sensor package, the method comprising:
providing an optically transmissive substrate;
patterning a first layer of an adhesive dam on a largest planar surface of the optically transmissive substrate;
applying an optically opaque layer directly onto the first layer;
bonding the optically transmissive substrate to a semiconductor substrate comprising a plurality of image sensor die using the optically opaque layer;
forming a plurality of electrical interconnects to the plurality of image sensor die; and
singulating the optically transmissive substrate and semiconductor substrate to form a plurality of image sensor packages.

16. The method of claim 15, wherein forming a plurality of electrical interconnects further comprises forming a plurality of through-silicon-vias in the semiconductor substrate to a plurality of bond pads of the plurality of image sensor packages.

17. The method of claim 15, wherein the plurality of image sensor die each comprise a plurality of bond pads and the optically opaque layer completely covers all of the plurality of bond pads.

18. The method of claim 15, wherein forming a plurality of electrical interconnects further comprises forming a redistribution layer on a side of the semiconductor substrate opposite that to which the optically transmissive substrate is bonded.

19. The method of claim 15, wherein forming a plurality of electrical interconnects further comprises coupling a substrate array to a side of the semiconductor substrate opposite that to which the optically transmissive substrate is bonded.

20. The method of claim 15, further comprising thinning the semiconductor substrate after bonding to the optically transmissive substrate.
